(19) United States
(12) Patent Application Publication
(10) Pub. No.: US 2006/0160265 A1
(43) Pub. Date: Jul. 20, 2006

(54) Method of manufacturing photoelectric conversion element, photoelectric conversion element, and electronic apparatus

(75) Inventors: Katsuyuki Morii, Lausanne (CH); Tsutomu Miyamoto, Shiojiri-shi (JP); Yuji Fujimori, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/331,122

(22) Filed: Jan. 13, 2006

(30) Foreign Application Priority Data
Jan. 14, 2005 (JP) 2005-008405
Mar. 3, 2005 (JP) 2005-059472
Dec. 8, 2005 (JP) 2005-355428

(51) Int. Cl. H01L 21/00

(52) U.S. Cl. 438/87

(57) ABSTRACT

A method of manufacturing a photoelectric conversion element, in which a first carrier transport layer, a dye layer, and a second carrier transport layer are interposed between an anode and a cathode, includes forming the first carrier transport layer, forming the dye layer so as to come into contact with the first carrier transport layer, forming the second carrier transport layer so as to come into contact with the dye layer, and forming at least one of the first carrier transport layer and the second carrier transport layer by a liquid film-deposition method.

### BACKGROUND

1. Technical Field

The present invention relates to a method of manufacturing a photoelectric conversion element, to a photoelectric conversion element, and to an electronic apparatus.

2. Related Art

In recent years, as a substitute of an amorphous silicon solar cell, a dye-sensitization-type solar cell has been suggested (for example, see JP-A-2004-235240).

In the solar cell (photoelectric conversion element) described in JP-A-2004-235240, a hole transport layer, a dye layer, and an electron transport layer are interposed between an anode and a cathode. Holes and electrons generated in the dye layer are drawn out through the hole transport layer and the electron transport layer, respectively.

In such a solar cell, in view of the improvement of its characteristics (power generation efficiency), it is important to sufficiently cause the dye layer to be brought into contact with the hole transport layer or the electron transport layer.

For example, when the electron transport layer is porous, and the hole transport layer does not sufficiently enter into voids of the electron transport layer, the dye layer does not sufficiently come into contact with the hole transport layer. Accordingly, there is a problem in that the holes generated in the dye layer is not efficiently delivered to the hole transport layer.

When such a problem occurs, the power generation efficiency of the solar cell may be extremely lowered.

### SUMMARY

An advantage of some aspects of the invention is that it provides a method of manufacturing a photoelectric conversion element which can manufacture a photoelectric conversion element having excellent photoelectric conversion efficiency, a photoelectric conversion element manufactured by such a method of manufacturing a photoelectric conversion element, and an electronic apparatus having such a photoelectric conversion element.

The above-described advantage can be achieved by aspects of the invention.

According to a first aspect of the invention, a method of manufacturing a photoelectric conversion element, in which a first carrier transport layer, a dye layer, and a second carrier transport layer are interposed between an anode and a cathode, includes forming the first carrier transport layer, forming the dye layer so as to come into contact with the first carrier transport layer, forming the second carrier transport layer so as to come into contact with the dye layer, and forming at least one of the first carrier transport layer and the second carrier transport layer by a liquid film-deposition method.

According to this configuration, a photoelectric conversion element having excellent photoelectric conversion efficiency can be manufactured. Further, the carrier transport layers can be easily formed at low cost, without needing large-scale equipments.

In the method of manufacturing a photoelectric conversion element according to the first aspect of the invention, it is preferable that the first carrier transport layer be a porous electron transport layer, and the second carrier transport layer be a hole transport layer. Further, in the forming of the second carrier transport layer, the hole transport layer may be formed by the liquid film-deposition method.

According to this configuration, a photoelectric conversion element having excellent photoelectric conversion efficiency can be manufactured.

In the method of manufacturing a photoelectric conversion element according to the first aspect of the invention, it is preferable that, in the forming of the second carrier transport layer, when the hole transport layer is formed by supplying a first liquid material containing a first semiconductor material and then supplying a second liquid material containing a second semiconductor material from a side of the electron transport layer opposite to the cathode, the first liquid material have viscosity lower than that of the second liquid material at normal temperature.

According to this configuration, a photoelectric conversion element having excellent photoelectric conversion efficiency can be manufactured.

In the method of manufacturing a photoelectric conversion element according to the first aspect of the invention, it is preferable that, in the forming of the second carrier transport layer, the first semiconductor material be filled so as to cover voids of the electron transport layer.

According to this configuration, even when the second liquid material having relatively high viscosity is used, a contact area of the dye layer and the hole transport layer can be sufficiently ensured.

In the method of manufacturing a photoelectric conversion element according to the first aspect of the invention, it is preferable that viscosity of the first liquid material at normal temperature be 1 to 5 cP.

According to this configuration, the first liquid material can reliably reach deep portions of the voids of the electron transport layer, and a resultant photoelectric conversion element can have improved photoelectric conversion efficiency.

In the method of manufacturing a photoelectric conversion element according to the first aspect of the invention, it is preferable that, in the forming of the second carrier transport layer, the first liquid material be supplied while vibration is applied to the electron transport layer and/or the first liquid material.

According to this configuration, the first liquid material can reliably reach the deep portions of the voids of the electron transport layer, and the resultant photoelectric conversion element can have markedly improved photoelectric conversion efficiency.

In the method of manufacturing a photoelectric conversion element according to the first aspect of the invention, it is preferable that vibration be applied by using supersonic waves.

According to this configuration, the first liquid material can easily reach the deep portions of the voids of the electron transport layer.

In the method of manufacturing a photoelectric conversion element according to the first aspect of the invention, it is preferable that an increase rate of viscosity of the first liquid material according to an increase in concentration of the first semiconductor material be lower than an increase rate of viscosity of the second liquid material according to an increase in concentration of the second semiconductor material.

According to this configuration, in case of forming the hole transport layer, even when a solvent is gradually volatilized from the first liquid material, viscosity of the first liquid material can be held sufficiently low. Therefore, the first liquid material can be easily handled, and thus the hole transport layer can be easily and reliably formed.

In the method of manufacturing a photoelectric conversion element according to the first aspect of the invention, it is preferable that the first semiconductor material and the second semiconductor material be organic high-molecular-weight materials.

In view of excellent hole transport ability, coatability, and film deposition property, the organic high-molecular-weight materials are preferably used.

In the method of manufacturing a photoelectric conversion element according to the first aspect of the invention, it is preferable that the first semiconductor material and the second semiconductor material be organic polymers of the same kind, and an average molecular weight of the first semiconductor material be smaller than an average molecular weight of the second semiconductor material.

According to this configuration, even when an interface is not formed in the hole transport layer or the interface is formed, adherence between the two organic polymers at the interface can be made extremely high. As a result, in the entire hole transport layer, the holes can be smoothly and reliably transported.

In the method of manufacturing a photoelectric conversion element according to the first aspect of the invention, it is preferable that the average molecular weight of the first semiconductor material be 10000 or less.

According to this configuration, even when the concentration of the first semiconductor material in the first liquid material is relatively high or the concentration is involuntarily made high, viscosity of the first liquid material can be maintained low.

In the method of manufacturing a photoelectric conversion element according to the first aspect of the invention, it is preferable that the average molecular weight of the second semiconductor material be 15000 or more.

According to this configuration, the organic polymer having a large molecular weight particularly has excellent high transport ability. Moreover, if the molecular weight of the organic polymer is increased and exceeds an upper limit value, undesirably, kinds of solvents, which are obtained by dissolving the organic polymer, are drastically decreased.

In the method of manufacturing a photoelectric conversion element according to the first aspect of the invention, it is preferable that the organic polymer be polyarylamine, fluorene-arylamine copolymer, fluorene-bithiophene copolymer, or its derivative.

These organic polymers have a relatively low molecular weight but excellent hole transport ability. Therefore, a resultant hole transport layer also has excellent hole transport ability.

In the method of manufacturing a photoelectric conversion element according to the first aspect of the invention, it is preferable that the first semiconductor material and the second semiconductor material be the same kind.

According to this configuration, even when the interface is not formed in the hole transport layer or the interface is formed, adherence between the two semiconductor materials at the interface can be made extremely high. As a result, in the entire hole transport layer, the holes can be smoothly and reliably transported.

In the method of manufacturing a photoelectric conversion element according to the first aspect of the invention, it is preferable that the first carrier transport layer be a hole transport layer, and the second carrier transport layer be an electron transport layer. Further, in the forming of the first carrier transport layer, the hole transport layer may be formed by a liquid film-deposition method.

According to this configuration, a selection range of a material forming the electron transport layer can be widened. Further, by suitably selecting and bonding a dye, the photoelectric conversion element having excellent power generation efficiency can be obtained.

In the method of manufacturing a photoelectric conversion element according to the first aspect of the invention, it is preferable that the hole transport layer be primarily formed of an organic polymer.

Preferably, the organic polymer has excellent hole transport ability. Further, since the organic polymer has relatively excellent chemical resistance (solvent resistance), when the dye layer is formed by the liquid film-deposition method, a selection range of a liquid, which is used to prepare a material for dye layer formation, can be widened. Further, by widening the selection range of the solution, a selection range of a dye to be used for the dye layer can be widened.

In the method of manufacturing a photoelectric conversion element according to the first aspect of the invention, it is preferable that an average molecular weight of the organic polymer be 8000 or more.

As such, by using the organic polymer having a relatively high average molecular weight, the above-described effect can be further improved.

In the method of manufacturing a photoelectric conversion element according to the first aspect of the invention, it is preferable that the organic polymer have an arylamine skeleton and/or a fluorene skeleton.

These organic polymers have excellent hole transport ability and chemical resistance.

In the method of manufacturing a photoelectric conversion element according to the first aspect of the invention, it is preferable that, in the forming of the dye layer, the dye layer be formed by the liquid film-deposition method, and a liquid, which is obtained by swelling the hole transport layer, be used to prepare a liquid material for dye layer formation.

According to this configuration, the interface of the dye layer and the hole transport layer can be microscopically made uneven in a concavo-convex shape, and thus the contact area of the dye layer and the hole transport layer can be increased. For this reason, the holes can be smoothly delivered from the dye layer to the hole transport layer, and thus power generation efficiency of the photoelectric conversion element can be improved.

In the method of manufacturing a photoelectric conversion element according to the first aspect of the invention, it is preferable that, as the liquid film-deposition method for forming the hole transport layer, a liquid droplet discharge method be used.

By using the liquid droplet discharge method, the hole transport layer can be precisely formed, without wasting the liquid material.

In the method of manufacturing a photoelectric conversion element according to the first aspect of the invention, it is preferable that, in the forming of the dye layer, the dye layer be formed by the liquid film-deposition method.

According to the liquid film-deposition method, the dye layer can be easily formed at low cost, without using large-scale equipments.

In the method of manufacturing a photoelectric conversion element according to the first aspect of the invention, it is preferable that, as the liquid film-deposition method for forming the dye layer, a liquid droplet discharge method be used.

By using the liquid droplet discharge method, the dye layer can be precisely formed, without wasting the liquid material.

The method of manufacturing a photoelectric conversion element according to the first aspect of the invention may further include, prior to forming the individual layers, forming a bank that defines a shape of a corresponding layer.

According to this configuration, the individual layers can be formed with high precision.

According to a second aspect of the invention, there is provided a photoelectric conversion element which is manufactured by the method of manufacturing a photoelectric conversion element of the invention.

According to this configuration, a photoelectric conversion element having excellent photoelectric conversion efficiency can be obtained.

According to a third aspect of the invention, an electronic apparatus includes the photoelectric conversion element of the invention.

According to this configuration, an electronic apparatus having high reliability can be obtained.

### BRIEF DESCRIPTION OF THE DRAWINGS

The invention will be described with reference to the accompanying drawings, wherein like numbers reference like elements.

FIG. 1 is a partial cross-sectional view showing a first embodiment when a photoelectric conversion element of the invention is applied to a solar cell.

FIG. 2 is an expanded view showing a section close to a central portion of the solar cell shown in FIG. 1 in a thicknesswise direction.

FIG. 3 is a schematic view showing configurations of an electron transport layer and a dye layer.

FIG. 4 is a longitudinal cross-sectional view showing a second embodiment when a photoelectric conversion element of the invention is applied to a solar cell.

FIG. 5 is an expanded view showing a section close to a central portion of the solar cell shown in FIG. 4 in a thicknesswise direction.

FIG. 6A is a diagram (longitudinal cross-sectional view) illustrating a manufacturing process of the solar cell shown in FIG. 4.

FIG. 6B is a diagram (longitudinal cross-sectional view) illustrating a manufacturing process of the solar cell shown in FIG. 4.

FIG. 6C is a diagram (longitudinal cross-sectional view) illustrating a manufacturing process of the solar cell shown in FIG. 4.

FIG. 6D is a diagram (longitudinal cross-sectional view) illustrating a manufacturing process of the solar cell shown in FIG. 4.

FIG. 6E is a diagram (longitudinal cross-sectional view) illustrating a manufacturing process of the solar cell shown in FIG. 4.

FIG. 6F is a diagram (longitudinal cross-sectional view) illustrating a manufacturing process of the solar cell shown in FIG. 4.

FIG. 7 is a plan view showing an electronic calculator, to which a photoelectric conversion element of the invention is applied.

FIG. 8 is a perspective view showing a cellular phone (including PHS), to which a photoelectric conversion element of the invention is applied.

### DESCRIPTION OF EXEMPLARY EMBODIMENTS

Hereinafter, a method of manufacturing a photoelectric conversion element, a photoelectric conversion element, and an electronic apparatus of the invention will be described by way of preferred embodiments with reference to the accompanying drawings.

First, an example when a photoelectric conversion element of the invention is applied to a solar cell will be described.

### First Embodiment

First, a first embodiment when a photoelectric conversion element of the invention is applied to a solar cell will be described.

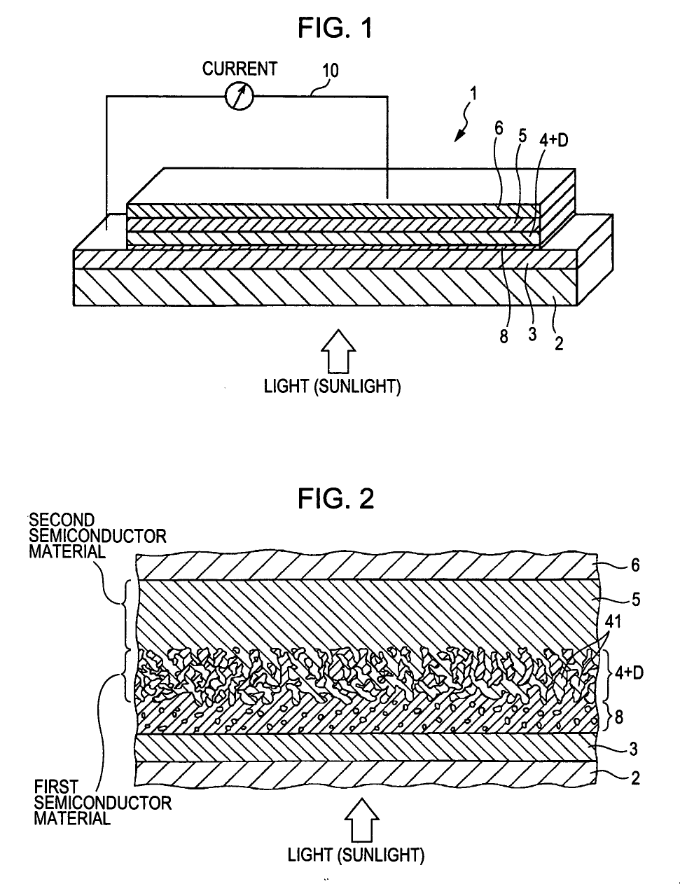

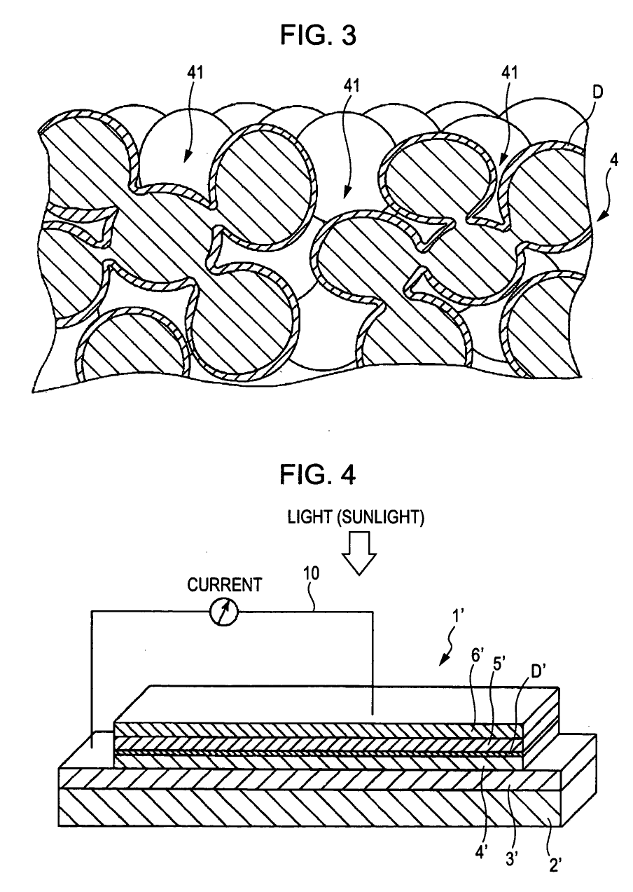

FIG. 1 is a partial cross-sectional view of the first embodiment when the photoelectric conversion element of the invention is applied to the solar cell. FIG. 2 is an expanded view showing a section close to a central portion of the solar cell shown in FIG. 1 in a thicknesswise direction. FIG. 3 is a schematic view showing the configurations of an electron transport layer and a dye layer. Hereinafter, for convenience of explanation, in FIGS. 1 to 3, an upper side is referred to as ‘top’, and a lower side is referred to as ‘bottom’.

The solar cell 1 shown in FIG. 1 has a cathode (first electrode) 3 provided on a substrate 2, an anode (second electrode) 6 provided to face the cathode 3, an electron transport layer (first carrier transport layer) 4 disposed on the cathode 3, a dye layer D which comes into contact with the electron transport layer 4, and a hole transport layer (second carrier transport layer) 5 which comes into contact with the dye layer D. The electron transport layer 4, the dye layer D, and the hole transport layer 5 are interposed between the electrodes 3 and 6.

Hereinafter, the configurations of the individual parts will be described. Hereinafter, for convenience of explanation, in FIGS. 1 to 3, the upper side is referred to as ‘top’, and the lower side is referred to as ‘bottom’.

The substrate 2 is provided to support the cathode 3, the electron transport layer 4, the dye layer D, the hole transport layer 5, and the anode 6. The substrate 2 is formed of a flat plate member.

In the solar cell 1 of the present embodiment, as shown in FIG. 1, for example, from the substrate 2 and the cathode 3 described below, light of sunlight or the like (hereinafter, simply referred to as ‘light’) is incident (irradiated) to be used. For this reason, preferably, the substrate 2 and the cathode 3 are substantially transparent (achromatic transparent, colored transparent, or translucent). Accordingly, light can efficiently reach the dye layer D described below.

As a forming material of the substrate 2, for example, a glass material, a ceramics material, a resin material, such as polycarbonate (PC) or polyethylene terephthalate (PET), a metal material, such as aluminum, or the like can be exemplified.

An average thickness of the substrate 2 is suitably set according to the forming material thereof, the use of the solar cell 1, or the like. The average thickness of the substrate 2 is not particularly limited, but, for example, can be set as follows.

If the substrate 2 is formed of a hard material, the average thickness thereof is preferably about 0.1 to 1.5 mm, and more preferably, about 0.8 to 1.2 mm. Further, if the substrate 2 is formed of a flexible material, the average thickness thereof is preferably about 0.5 to 150 μm, and more preferably, about 10 to 75 μm.

Moreover, if necessary, the substrate 2 can be omitted.

On the substrate 2 (one surface of the substrate 2), the cathode 3 is provided. The cathode 3 receives holes generated in the dye layer 4 described layer D through the electron transport layer 4, and transfers the holes to an external circuit 10 connected thereto.

As a forming material of the cathode 3, for example, metal oxide materials, such as indium tin oxide (ITO), tin oxide having fluorine atoms (FTO), indium oxide (IO), tin oxide (SnO₂), and the like, metal materials, such as aluminum, nickel, cobalt, platinum, silver, gold, copper, molybdenum, titanium, tantalum, and an alloy of them, carbon materials, such as graphite, or the like can be exemplified. One kind of the materials or a mixture of two or more kinds of them (for example, a laminate of multiple layers) can be used.

An average thickness of the cathode 3 is suitably set according to the forming material thereof, the use of the solar cell 1, or the like. The average thickness of the cathode 3 is not particularly limited, but, for example, can be set as follows.

If the cathode 3 is formed of a metal oxide material (transparent conductive metal oxide material), the average thickness thereof is preferably about 0.05 to 5 μm, and more preferably, about 0.1 to 1.5 μm. Further, if the cathode 3 is formed of a metal material or a carbon material, the average thickness thereof is preferably about 0.01 to 1 μm, and more preferably, about 0.03 to 0.1 μm.

Moreover, the cathode 3 is not limited to a shape shown in the drawings. For example, the cathode 3 can have a comb shape having plural teeth or the like. In this case, light transmits among the plural teeth and reaches the dye layer D, and thus the cathode 3 may be not substantially transparent. Accordingly, a selection range of the forming material or the forming method (manufacturing method) of the cathode 3 can be widened.

Further, as the cathode 3, a combination of the comb-shaped electrode and a layered electrode (for example, a laminate) can be used.

On the cathode 3, a film-shaped barrier layer 8 and the porous electron transport layer 4 are sequentially provided.

The electron transport layer 4 has at least a function of transporting electrons generated in the dye layer D.

As a forming material of the electron transport layer 4, one kind of various organic or inorganic n-type semiconductor materials or a mixture of two or more kinds of them can be used. Of them, as the inorganic n-type semiconductor material, for example, an oxide semiconductor material, such as titanium oxide of titanium dioxide (TiO₂), titanium monoxide (TiO), titanium trioxide (Ti₂O₃), or the like, zinc oxide (ZnO), or tin oxide (SnO₂) can be suitably used.

Of them, as the forming material of the electron transport layer 4, a material primarily containing titanium dioxide is preferably used. Since titanium dioxide has excellent electron transport ability and high photosensitivity, the electron transport layer 4 itself can generate electrons. As a result, the solar cell 1 has improved power generation efficiency (photoelectric conversion efficiency).

Further, since titanium dioxide has a stable crystal structure, even when the electron transport layer 4 primarily containing titanium dioxide is under a harsh environment, an annual change (degradation) is small, and thus a stable performance can be kept for a long time.

In addition, titanium dioxide may be one primarily containing a material having an anatase crystal structure, one primarily containing a material having a rutile crystal structure, or a mixture of the material having the anatase crystal structure and the material having the rutile crystal structure.

Moreover, when rutile titanium dioxide and anatase titanium dioxide are mixed, the mixture ratio is not particularly limited. For example, the mixture ratio is preferably about 95:5 to 5:95 by weight, and more preferably, about 80:20 to 20:80.

The electron transport layer 4 is formed of, for example, an aggregate of granular bodies (particles) or tubular bodies of the above-described n-type semiconductor material, or a mixture of them or the like.

In particular, by using the tubular bodies, an electron propagation speed in the electron transport layer 4 can be improved. As a result, the recombination of the electrons and holes can be reliably prevented or suppressed. Further, a specific surface area of the electron transport layer 4 can be increased, which causes an increase in dye combination amount. For this reason, power generation efficiency of the solar cell 1 can be improved.

When the granular bodies are used, the average particle size of them is preferably about 1 nm to 1 μm, and more preferably, about 5 to 50 nm. Further when the tubular bodies are used, the average length of them is preferably in the above-described range. Accordingly, the above-described effect can be further improved.

Further, on an outer surface of the electron transport layer 4 and an inner surface of each of voids 41, a coat layer having a function of preventing or suppressing the electrons received by the dye layer D from being moved to the dye layer D again (reverse electron movement) may be formed. Accordingly, the recombination of the electrons and holes can be reliably prevented or suppressed.

The coat layer can be formed of a material having a bottom potential of a conduction band lower than a bottom potential of a conduction band of the n-type semiconductor material forming the electron transport layer 4, that is, a material having the bottom potential of the conduction band close to a valance band rather than the bottom potential of the conduction band of the n-type semiconductor material forming the electron transport layer 4.

As such a material, when a material primarily containing titanium dioxide is used as the n-type semiconductor material, one kind of zirconium oxide, strontium titanate, niobium oxide, magnesium oxide, zinc oxide, and tin oxide or a mixture of two or more kinds of them can be used.

The average thickness of such a coat layer is preferably about 0.1 to 10 nm.

Further, at a contact interface of the granular bodies, the tubular bodies, and the granular bodies and the tubular bodies, preferably, the bodies are sufficiently diffused and combined. Accordingly, in the electron transport layer 4, the electron movement is prevented from being suppressed, and thus the recombination of the electrons and holes can be reliably prevented or suppressed.

This can be performed, for example, by forming the electron transport layer 4, dissolving the peripheries of surfaces of the granular bodies or the tubular bodies, and then firing the electron transport layer 4 at about 400 to 500° C. again.

In order to dissolve the peripheries of the surfaces of the granular bodies or the tubular bodies, for example, an acid solution, such as hydrochloric acid, nitric acid, acetic acid, or fluoric acid, or an alkaline solution containing sodium hydroxide, magnesium hydroxide, or potassium hydroxide can be used.

A void ratio of such an electron transport layer 4 is not particularly limited. For example the void ratio is preferably about 5 to 90%, more preferably, about 15 to 50%, and, still more preferably, about 20 to 40%. By setting the void ratio of the electron transport layer 4 in such a range, a specific surface area of the electron transport layer 4 can be sufficiently made large. Accordingly, the forming area (forming region) of the dye layer D (described below) to be formed on the outer surface of the electron transport layer 4 and the inner surfaces of the voids 41 can also be made large. For this reason, in the dye layer D, sufficient electrons can be generated, and the electrons can be efficiently delivered to the electron transport layer 4. As a result, power generation efficiency of the solar cell 1 can be further improved.

Further, the average thickness of the electron transport layer 4 is not particularly limited. For example, the average thickness of the electron transport layer 4 is preferably about 0.1 to 300 μm, more preferably, about 0.5 to 100 μm, and, still more preferably, about 1 to 25 μm.

A void ratio of the barrier layer 8 is set lower than that of the electron transport layer 4 so as to prevent or suppress the hole transport layer 5 (first semiconductor material) described below and the cathode 3 from being brought into contact with each other. Accordingly, leakage current can be prevented from occurring, and thus power generation emission efficiency of the solar cell 1 can be prevented from being lowered.

Here, when the void ratio of the barrier layer 8 is A%, and the void ratio of the electron transport layer 4 is B%, B/A is preferably 1.1 or more, more preferably, 5 or more, and still more preferably, 10 or more. Accordingly, the barrier layer 8 and the electron transport layer 4 can suitably exhibit the individual functions.

Specifically, the void ratio A of the barrier layer 8 is preferably 20% or less, more preferably 5% or less, and still more preferably, 2% or less. That is, the barrier layer 8 is preferably a dense layer. Accordingly, the above-described effect can be further improved.

In addition, the thickness ratio of the barrier layer 8 to the electron transport layer 4 is not particularly limited. For example, the thickness ratio of the barrier layer 8 to the electron transport layer 4 is preferably about 1:99 to 60:40, and more preferably, about 10:90 to 40:60. That is, in the total thickness of the barrier layer 8 and the electron transport layer 4, the thickness ratio of the barrier layer 8 is preferably about 1 to 60%, and more preferably, about 10 to 40%. Accordingly, the barrier layer 8 can reliably prevent or suppress short-circuit due to the contact of the cathode 3 and the hole transport layer 5 or the like. At the same time, an irradiation ratio of light onto the dye layer D can be suitably prevented from being lowered.

Specifically, the average thickness (film thickness) of the barrier layer 8 is preferably about 0.01 to 10 μm, more preferably, about 0.1 to 5 μm, and still more preferably, about 0.5 to 2 μm. Accordingly, the above-described effect can be further improved.

A forming material of the barrier layer 8 is not particularly limited. For example, in addition to titanium oxide, which is the primary forming material of the electron transport layer 4, SrTiO₃, ZnO, SiO₂, Al₂O₃, SnO₂, CdS, CdSe, TiC, Si₃N₄, SiC, B₄N, BN, or the like can be exemplified. Further, one kind of them or a mixture of two or more kinds of them can be used.

Of them, as the forming material of the barrier layer 8, a material having the same electrical conductivity as that of the electron transport layer 4 is preferably used. In particular, a material primarily having titanium dioxide is more preferably used. By forming the barrier layer 8 of such a material, the electrons generated in the dye layer D can be efficiently transferred from the electron transport layer 4 to the barrier layer 8. As a result, power generation efficiency of the solar cell 1 can be further improved.

A resistance value of the barrier layer 8 or the electron transport layer 4 in its thicknesswise direction is not particularly limited. In the barrier layer 8 and the electron transport layer 4 in total (that is, a laminate), the resistance value in the thicknesswise direction is preferably 100 Ω/cm² or more, and more preferably, 1 kΩ/cm². Accordingly, leakage (short-circuit) between the cathode 3 and the hole transport layer 5 can be reliably prevented or suppressed, and thus power generation efficiency of the solar cell 1 can be reliably prevented from being lowered.

Further, an interface of the barrier layer 8 and the electron transport layer 4 may be clear or not clear, but preferably not clear (unclear). That is, preferably, the barrier layer 8 and the electron transport layer 4 are integrally formed and partially overlap each other. Accordingly, the electrons can be reliably (efficiently) transferred (delivered) between the barrier layer 8 and the electron transport layer 4.

In addition, the barrier layer 8 and the electron transport layer 4 may be formed of materials having the same composition (for example, materials primarily containing titanium dioxide), but may have different void ratios. That is, a part of the electron transport layer 4 may function as the barrier layer 8.

In this case, the electron transport layer 4 has a dense portion and a sparse portion in the thicknesswise direction, and the dense portion functions as the barrier layer 8.

Further, in this case, the dense portion is preferably formed in the electron transport layer 4 close to the cathode 3. Alternatively, the dense portion may be formed at an arbitrary position in the thicknesswise direction.

Further, in this case, the electron transport layer 4 may have a configuration in which the sparse portion is interposed between the dense portions or a configuration in which the dense portion is interposed between the sparse portions.

In such an electron transport layer 4, by causing the dye to be absorbed or bonded (covalent bond or coordinate bond), the dye layer D is provided so as to come into contact with the electron transport layer 4.

The dye layer D is a light-receiving layer, which receives light so as to generate the electrons and the holes. As shown in FIG. 3, the dye layer D is formed on the outer surface of the electron transport layer 4 and the inner surfaces of the voids 41. Accordingly, the electrons generated in the dye layer D can be efficiently delivered to the electron transport layer 4.

As a dye forming the dye layer D, pigments or dyes can be used singly or in combination. Moreover, in view of small time-variant change and degradation, it is preferable to use pigments. On the other hand, in view of excellent absorption to (bonding with) the electron transport layer 4, it is preferable to use dyes.

Here, as the pigments, various pigments, such as organic pigments, inorganic pigments, and the like, can be used. As the organic pigments, phthalocyanine-based pigments, such as phthalocyanine green, phthalocyanine blue, and the like, azo-based pigments, such as fast yellow, disazo yellow, condensed azo yellow, benzimidazolone yellow, dinitroaniline orange, benzimidazolone orange, toluidine red, permanent carmine, permanent red, naphthol red, condensed azo red, benzimidazolone carmine, benzimidazolone brown, and the like, anthraquinone-based pigments, such as anthrapyrimidine yellow, anthraquinonyl red, and the like, azomethine-based pigments, such as azomethine yellow (copper) and the like, quinophthalone-based pigments, such as quinophthalone yellow and the like, isoindoline-based pigments, such as isoindoline yellow and the like, nitroso-based pigments, such as dioxine yellow (nickel) and the like, perinone-based pigments, such as perinone orange and the like, quinacridone-based pigments, such as quinacridone magenta, quinacridone maroon, quinacridone scarlet, quinacridone red, and the like, perylene-based pigments, such as perylene red, perylene maroon, and the like, pyrropyrrol-based pigments, such as diketo pyrropyrrol red and the like, and dioxazine-pigments, such as dioxazine violet and the like, can be exemplified. As the inorganic pigments, carbon-based pigments, such as carbon black, lamp black, furnace black, ivory black, graphite, fullerene, and the like, chromate-based pigments, such as chrome yellow, molybdate orange, and the like, sulfide-based pigments, such as cadmium yellow, cadmium lithopone yellow, cadmium orange, cadmium lithopone orange, vermilion, cadmium red, cadmium lithopone red, and the like, oxide-based pigments, such as ochre, titanium yellow, titanium-barium-nickel yellow, red iron oxide, red lead, umber, brown iron oxide, zinc iron chromite brown, chromium oxide, cobalt green, cobalt chromite green, cobalt titanate green, cobalt blue, cerulean blue, cobalt-aluminum-chromium blue, black iron oxide, manganese ferrite black, cobalt ferrite black, copper chromite black, copper chromite manganese black, and the like, hydroxide-based pigments, such as viridian and the like, ferrocyanide-based pigments, such as Prussian blue and the like, silicate-based pigments, such as ultramarine blue and the like, phosphate-based pigments, such as cobalt violet, mineral violet, and the like, and other pigments (such as cadmium sulfide, cadmium selenide, and the like), can be exemplified. In this case, one kind of these pigments or a mixture of two or more kinds of them can be used.

On the other hand, as the dyes, for example, metal complex dyes, such as RuL₂(SCN)₂, RuL₂Cl₂, RuL₂(CN)₂, Rutenium535-bisTBA (available from Solaronics, Inc.), and [RuL₂(NCS₂)₂]H₂O, and the like, cyan-based dyes, xanthene-based dyes, azo-based dye, hibiscus dyes, black berry dyes, raspberry dyes, pomegranate juice dyes, and chlorophyll dyes can be exemplified. In this case, one kind of these dyes or a mixture of two or more kinds of them can be used. Moreover, L in the above-described chemical formula indicates 2,2′-bipyridine or derivatives thereof.

The hole transport layer 5 is provided so as to come into contact with the dye layer D. The hole transport layer 5 has a function of capturing and transporting the holes generated in the dye layer D.

The hole transport layer 5 is a layered shape as a whole, but, as shown in FIG. 2, on the electron transport layer 4, a part of the hole transport layer 5 enters into each of the voids 41 of the electron transport layer 4. Accordingly, the contact area of the dye layer D and the hole transport layer 5 can be increased, and the holes generated in the dye layer D can be efficiently delivered to the hole transport layer 5. As a result, power generation efficiency of the solar cell 1 can be further improved.

As a forming material of the hole transport layer 5, various p-type semiconductor materials are used. For example, organic polymers, such as polyarylamine, fluorene-arylamine copolymer, fluorene-bithiophene copolymer, poly(N-vinylcarbazole), polyvinylpyrene, polyvinylanthracene, polythiophene, polyalkylthiophene, polyhexylthiophene, (p-phenylenevinylene), polythenylenevinylene, pyrene-formaldehyde resin, ethylcarbazole-formaldehyde resin, or derivatives of them, organic high-molecular-weight materials, such as dendrimer having a fluorene skeleton or the like, organic low-molecular-weight materials, such as naphthalene, anthracene, tetracene, pentacene, hexacene, phthalocyanine, perylene, hydrazone, triphenylmethane, diphenylmethane, stilbene, arylvinyl, pyrazoline, triphenylamine, triarylamine, oligothiophene, phthalocyanine, or derivatives of them, and inorganic materials, such as CuI, AgI, AgBr, CuSCN, and the like, can be exemplified. One kind of these materials or a mixture of two or kinds of them can be used.

Further, these organic polymers can be used in combination with other polymers. For example, as a mixture containing polythiophene, poly(3,4-ethylenedioxythiophene/polystyrene sulfonic acid) (PEDOT/PSS) or the like can be exemplified.

In addition, an average thickness of the hole transport layer 5 (excluding the part entered into the void 41) is not particularly limited. For example, the average thickness of the hole transport layer 5 is preferably about 1 to 500 μm, more preferably, about 10 to 300 μm, and, still more preferably, about 10 to 30 μm.

On the hole transport layer 5 (a side opposite to the cathode 3), the anode 6 is provided so as to face the cathode 3.

As a forming material of the anode 6, for example, a metal, such as aluminum, nickel, cobalt, platinum, silver, gold, copper, molybdenum, titanium, tantalum, or an alloy containing them, or various carbon materials, such as graphite or the like, can be exemplified. One of kind of these materials or a mixture of two or more kinds of them can be used.

An average thickness of the anode 6 is suitably set according to the forming material or the use of the solar cell 1, and is not particularly limited.

In such a solar cell 1, if light is incident, the electrons are primarily excited in the dye layer D, and thus the electrons (e⁻) and the holes (h⁺) are generated. Of them, the electrons move to the electron transport layer 4, and the holes move to the hole transport layer 5. As a result, a potential difference (photovoltaic force) is generated between the cathode 3 and the anode 6, and a current (photoexcited current) flows in the external circuit 10.

Further, in such a solar cell 1, when a voltage of 0.5 V is applied in a state in which the cathode 3 is positive and the anode 6 is negative, it is preferable that the resistance value be 100 Ω/cm² or more (more preferably, 1 kΩ/cm² or more). In the solar cell 1 having such a characteristic, short-circuit (leakage) due to the contact of the cathode 3 and the hole transport layer 5 or the like can be suitably prevented or suppressed, and thus power generation efficiency (photoelectric conversion efficiency) can be further improved.

Such a solar cell 1 can be manufactured as follows, for example.

[1] A laminate of the substrate 2, the cathode 3, the barrier layer 8, and the electron transport layer 4 is prepared (First Step).

[1-1] First, the substrate 2 is prepared, and the cathode 3 is formed on the substrate 2.

The cathode 3 can be formed by a vapor deposition method, a sputtering method, a printing method, or the like.

[1-2] Next, the barrier layer 8 is formed on the cathode 3.

The barrier layer 8 can be formed by a sol-gel method, a deposition (vacuum deposition) method, a sputtering method (high-frequency sputtering, DC sputtering), a spray thermal decomposition method, a jet molding (plasma spraying) method, a CVD method, or the like. Among these methods, it is preferable to form the barrier layer 8 by the sol-gel method.

The operation of the sol-gel method is extremely simple. Further, by using the sol-gel method, the forming material of the barrier layer 8 can be supplied by various coating methods, such as a dipping method, dripping, a doctor blade method, a spin coating method, brushing, a spray coating method, a roll coating method, and the like. As a result, the barrier layer 8 having a desired film thickness can be easily formed, without using large-scale equipments.

In particular, in order to form the barrier layer 8, it is preferable to use a metal organic deposition (or decomposition) method (hereinafter, simply referred to as ‘MOD method’), which is a kind of sol-gel method.

According to the MOD method, the reactions (for example, hydrolysis, condensation polymerization, and the like) of precursors in the material for barrier layer formation are prevented. Therefore, the barrier layer 8 can be formed easily and reliably (with high reproducibility). Further, the resultant barrier layer 8 can be made dense (to have the void ratio within the above-described range.

When the barrier layer 8 is primarily formed of titanium dioxide, as the precursor, for example, organic titanium compound, such as titanium tetraisopropoxide (TPT), titanium tetramethoxide, titanium tetraethoxide, titanium tetrabutoxide, or the like, can be used.

[1-3] Next, the electron transport layer 4 is formed on the barrier layer 8.

The electron transport layer 4 can be formed by supplying the material for electron transport layer formation containing the above-described granular bodies and/or tubular bodies on the barrier layer 8, removing a dispersion medium, and then firing.

As a method of supplying the material for electron transport layer formation, various coating methods described above can be used.

[2] Next, the dye layer D is formed so as to come into contact with the electron transport layer 4 (Second Step).

The dye layer D can be formed by causing a liquid containing a dye to come into contact with the electron transport layer 4, and then removing a solvent (or a dispersion medium).

Accordingly, the dye is absorbed and bonded to the outer surface of the electron transport layer 4 and the inner surfaces of the voids 41, and thus the dye layer D is formed along the surfaces.

As a method of causing the liquid containing the dye to come into contact with the electron transport layer 4, for example, a method of immersing the laminate in the liquid containing the dye (immersion method), a method of coating the liquid containing the dye to the electron transport layer 4 (coating method), or a method of supplying the liquid containing the dye to the electron transport layer 4 in a shower shape can be exemplified.

As the solvent (or the dispersion medium) for preparing the liquid containing the dye, for example, various kinds of water, methanol, ethanol, isopropyl alcohol, acetonitrile, ethyl acetate, ether, methylene chloride, NMP (N-methyl-2-pyrrolidone) or the like can be exemplified. One kind of the materials or a mixture of two or more kinds of them can be used.

Further, as a method of removing the solvent, for example, a method of leaving the laminate under an air pressure or under a reduced pressure, or a method of blowing gas, such as air, nitrogen gas, or the like at the laminate can be exemplified.

Moreover, if necessary, a heat treatment may be performed on the laminate at a temperature of about 60 to 100° C. for about 0.5 to 2 hours. Accordingly, it is possible to let the dye absorbed (bonded) to the electron transport layer 4 firmly.

[3] Next, the hole transport layer 5 is formed so as to come into contact with the dye layer D (Third Step).

The hole transport layer 5 is formed by supplying a first liquid material containing a first semiconductor material and then supplying a second liquid material containing a second semiconductor material from an upper side of the electron transport layer 4 (a side of the electron transport layer 4 opposite to the cathode 3), on which the dye layer D is formed. That is, the hole transport layer 5 is formed by a liquid film-deposition method. By forming the hole transport layer 5 by the liquid film-deposition method, the contact area of the dye layer D and the hole transport layer 5 can be increased, and the holes can be efficiently delivered from the dye layer D to the hole transport layer 5. Accordingly, the recombination of the holes and electrons can be reliably prevented. As a result, power generation efficiency (photoelectric conversion efficiency) of the solar cell 1 can be improved.

At this time, in the present embodiment, viscosity of the first liquid material is set lower than that of the second liquid material at normal temperature. Accordingly, the first liquid material (first semiconductor material) reaches deep portions of the voids 41 of the electron transport layer 4, that is, the barrier layer 8 or its periphery. As a result, the contact area of the dye layer D and the hole transport layer 5 can be increased, and the holes can be efficiently delivered from the dye layer D and the hole transport layer 5. Accordingly, the recombination of the holes and electrons can be reliably prevented. For this reason, power generation efficiency (photoelectric conversion efficiency) of the solar cell 1 can be improved.

Viscosity of the first liquid material at normal temperature is preferably about 1 to 5 cP, and more preferably, about 1 to 3 cP. Accordingly, the first liquid material reliably reaches the deep portions of the voids 41 of the electron transport layer 4. As a result, the above-described effect can be markedly exhibited.

The supply amount of the first liquid material is arbitrary. For example, it is preferable to fill the first semiconductor material so as to cover the voids 41 of the electron transport layer 4. Accordingly, when the second liquid material having relatively high viscosity is used, the contact area of the dye layer D and the hole transport layer 5 can be sufficiently ensured.

At this time, it is preferable to supply the first liquid material while vibration is applied to one or both of the electron transport layer 4 and the first liquid material. Accordingly, the first liquid material reliably reaches the deep portions of the voids 41 of the electron transport layer 4, and thus the above-described effect can be markedly exhibited.

As a method of applying vibration, for example, a method of applying supersonic waves to the substrate 2 (the electron transport layer 4), a method of using supersonic waves, such as a method of coating (supplying) liquid droplets (the first liquid material) to which supersonic waves are applied, or a method of applying a mechanical impact can be exemplified. Among these, in particular, it is preferable to use the method of using the supersonic waves. Accordingly, the first liquid material can easily reach the deep portions of the voids 41 of the electron transport layer 4.

The first liquid material has lower viscosity than that of the second liquid material at normal temperature. In particular, it is preferable that an increase rate of viscosity of the first liquid material according to an increase in concentration of the first semiconductor material be lower than an increase rate of viscosity of the second liquid material according to an increase in concentration of the second semiconductor material. Accordingly, in a case of forming the hole transport layer 5, even when the solvent is gradually volatilized from the first liquid material, it is possible to keep viscosity of the first liquid material low. Further, it is possible to easily handle the first liquid material. As a result, the hole transport layer 5 can be easily and reliably formed.

Further, as the first semiconductor material and the second semiconductor material, among the above-described materials, a proper combination is arbitrarily selected so as to cause the hole transport layer 5 to exhibit excellent characteristics. As the first semiconductor material and the second semiconductor material, it is preferable to use organic high-molecular-weight materials. In view of excellent hole transport ability, coatability, and film deposition property, the he organic high-molecular-weight materials are preferably used.

When the organic high-molecular-weight materials are used as the first semiconductor material and the second semiconductor material, the preparation of viscosity of the first liquid material and the second liquid material can be performed by suitably setting at least one condition of average molecular weight, kind, and concentration of the organic high-molecular-weight material, a kind of the solvent, a process temperature at the time of coating, and the like.

For example, I: a method of using organic polymers of the same kind as the first semiconductor material and the second semiconductor material, and selecting the first semiconductor material a smaller average molecular weight than an average molecular weight of the second semiconductor material, and II: a method of selecting dendrimer as the first semiconductor material, and selecting organic polymer as the second semiconductor material can be exemplified. Of them, in particular, it is preferable to use the method I.

Here, in general, when the hole transport layer 5 is formed by using two kinds of semiconductor materials, an interface between these semiconductor materials is formed. On the other hand, according to the method I, since the organic polymers of the same kind are used as the first semiconductor material and the second semiconductor material, even when the interface is not formed or the interface is formed, adherence of the two organic polymers (semiconductor materials) at the interface is extremely made high. Further, since the second semiconductor material has a relatively high molecular weight, film deposition property is excellent, and thus a uniform layer can be formed on the anode 6 with uniform quality. For this reason, the holes can be smoothly and reliably transported in the entire hole transport layer 5. Further, mechanical strength of the hole transport layer 5 can be prevented from being lowered, and durability and reliability of the solar cell 1 can be improved.

Further, in case of the method I, the average molecular weight of the first semiconductor material is preferably 10000 or less, and more preferably, about 1000 to 8000. Accordingly, even when the concentration of the first semiconductor material in the first liquid material is made relatively high, or the concentration is involuntarily made high, viscosity of the first liquid material can be maintained low.

On the other hand, the average molecular weight of the second semiconductor material is preferably 15000 or more, and more preferably, about 17000 to 25000. As such, the organic polymer having a high molecular weight has excellent hole transport ability. Moreover, if the molecular weight is increased and exceeds an upper limit value, undesirably, kinds of solvents, which are obtained by dissolving the organic polymer, are drastically decreased.

As the organic polymer, among the above-described materials, in particular, polyarylamin, fluorene-arylamine copolymer, fluorene-bithiophene copolymer, or derivatives of them are suitably used. These organic polymers have a relatively low molecular weight but has excellent hole transport ability. Accordingly, the resultant hole transport layer 5 also has excellent hole transport ability.

As the solvents for preparing the first liquid material and the second liquid material, materials obtained by dissolving the first semiconductor material and the second semiconductor material may be suitably selected. However, the solvents are not particularly limited.

Moreover, when the above-described organic polymers are used as the first semiconductor material and the second semiconductor material, for example, aromatic-based solvents, such as benzene, toluene, xylene, trimethylbenzene, tetramethylbenzene, cyclohexylbenzene, and the like, halide solvents, such as chlorobenzene, bromobenzene, and the like, or chloroform can be exemplified. These solvents can be used singly or in combination.

In particular, in order to prepare the first liquid material, it is preferable to use a solvent having high solubility to the first semiconductor material and a low boiling point, which can suppress cohesion of the first semiconductor material. As such a solvent, for example, toluene, chloroform, benzene, cyclohexane, methylcyclohexane, methylcyclopentane, cyclohexane, a mixed solvent containing them, or the like is suitably used.

Further, as a method of supplying the first liquid material and the second liquid material, for example, a dipping method, a spin coating method, a casting method, a micro gravure coating method, a gravure coating method, a bar coating method, a wire bar coating method, a roll coating method, a spray coating method, a screen printing method, a flexography method, an offset method, an ink jetting method, a micro contact printing method, or the like can be exemplified. One kind of these methods or a combination of two or more kinds of them can be used.

Moreover, as the method of supplying the first liquid material, it is preferable to use the spin coating method, which easily controls drying time. On the other hand, as the method of supplying the second liquid material, it is preferable to use the ink jetting method, which is hard to have influence on the first semiconductor material previously supplied.

Further, after the first liquid material and the second liquid material are supplied, if necessary, drying may be performed thereon.

Further, the first liquid material and the second liquid material may be supplied repeatedly.

In the present embodiment, the combination of the first semiconductor material and the second semiconductor material, all of which are formed of the organic polymer, has been described. Alternatively, a combination of the first semiconductor material formed of an inorganic material and the second semiconductor material formed of organic polymer, or a combination of the first semiconductor material and the second semiconductor material, all of which are formed of the inorganic material or the organic polymer can be exemplified.

Moreover, when the inorganic material is used for both the first semiconductor material and the second semiconductor material, it is preferable to use inorganic materials of the same kind.

Further, after the second liquid material containing the second semiconductor material is supplied, a third liquid material containing a third semiconductor material may be further supplied.

[4] Next, the anode 6 is formed on the hole transport layer 5 (Fourth Step).

The anode 6 can be formed by using a vapor deposition method, a sputtering method, a printing method, or the like.

[5] Next, end portions of the external circuit 10 are correspondingly connected to the cathode 3 and the anode 6.

Through the above-described steps, the solar cell 1 of the first embodiment (the photoelectric conversion element of the invention) is manufactured.

Moreover, prior to forming the individual layers, as described in a second embodiment, a bank for defining the shape of the corresponding layer may be formed.

### Second Embodiment

Next, a second embodiment when a photoelectric conversion element of the invention is applied to a solar cell will be described.

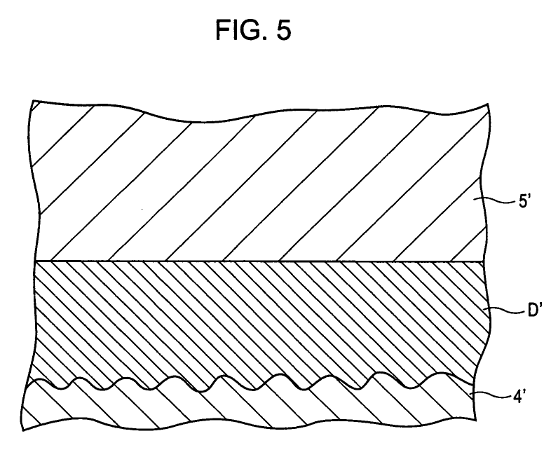

FIG. 4 is a longitudinal cross-sectional view showing the second embodiment when the photoelectric conversion element of the invention is applied to the solar cell. FIG. 5 is an expanded view showing the section close to the central portion of the solar cell shown in FIG. 4 in the thicknesswise direction. Moreover, hereinafter, for convenience of explanation, in FIGS. 4 and 5, the upper side is referred to as ‘top’, and the lower side is referred to as ‘bottom’.

The solar cell 1′ shown in FIG. 4 is configured such that an anode 3′, a hole transport layer (first carrier transport layer) 4′, a dye layer D′, an electron transport layer (second carrier transport layer) 5′, and a cathode 6′ are sequentially laminated on a substrate 2′.

Hereinafter, the configurations of the individual parts will be described.

The substrate 2′ supports the anode 3′, the hole transport layer 4′, the dye layer D′, the electron transport layer 5′, and the cathode 6′. The substrate 2′ is formed of a flat plate member.

In the solar cell 1′ of the present embodiment, as shown in FIG. 4, light of sunlight or the like (hereinafter, simply referred to as ‘light’) is incident (irradiated) from the cathode 6′ to be used. For this reason, the substrate 2′ and the anode 3′ are not necessarily transparent.

As the substrate 2′, for example, a transparent substrate formed of a resin material, such as polyethylene terephthalate, polyethylene naphthalate, polypropylene, cycloolefin polymer, polyamide, polyether sulfone, polymethyl methacrylate, polycarbonate, polyarylate, or the like, or a glass material, such as quartz glass, soda glass, or the like, or a nontransparent substrate of a substrate formed of a ceramics material, such as alumina or the like, a metal substrate formed of stainless steel with an oxide film (insulating film) formed on its surface, a substrate formed of a nontransparent resin material, or the like, can be used.

The average thickness of the substrate 21 is suitably set according to the forming material, the use of the solar cell 11, or the like, but is not particularly limited. For example, the average thickness of the substrate 2′ can be set as follows.

When the substrate 2′ is formed of a hard material, the average thickness is preferably about 0.1 to 1.5 mm, and more preferably, about 0.8 to 1.2 mm. Further, when the substrate 2′ is formed of a flexible material, the average thickness is preferably about 0.5 to 150 μm, and more preferably, about 10 to 75 μm.

Moreover, if necessary, the substrate 2′ may be omitted.

The anode 3′ is formed on the substrate 2′.

As the forming material of the anode 3′, for example, a metal, such as aluminum, nickel, cobalt, platinum, silver, gold, copper, molybdenum, titanium, tantalum, an alloy containing them, or various carbon materials, such as graphite, or the like can be exemplified. One kind of the materials or a mixture of two or more kinds of them can be used.

The average thickness of the anode 3′ is suitably set according to the forming material, the use of the solar cell 1′, or the like, but is not particularly limited.

The hole transport layer 4′ is formed on the anode 3′.

The hole transport layer 4′ has a function of capturing and transporting at least the holes generated in the dye layer D′.

As the forming material of the hole transport layer 4′, various p-type semiconductor materials are used. For example, organic polymers, such as polyarylamine, fluorene-arylamine copolymer, fluorene-bithiophene copolymer, poly(N-vinylcarbazole), polyvinylpyrene, polyvinylanthracene, polythiophene, polyalkylthiophene, polyhexylthiophene, (p-phenylenevinylene), polythenylenevinylene, pyrene-formaldehyde resin, ehtylcarbazole-formaldehyde resin, or derivatives of them, organic high-molecular-weight materials, such as dendrimer having a fluorene skeleton or the like, organic low-molecular-weight materials, such as naphthalene, anthracene, tetracene, pentacene, hexacene, phthalocyanine, perylene, hydrazone, triphenylmethane, diphenylmethane, stilbene, arylvinyl, pyrazoline, triphenylamine, triarylamine, oligothiophene, phthalocyanine, or derivatives of them, and inorganic materials, such as CuI, AgI, AgBr, CuSCN, and the like, can be exemplified. One kind of these materials or a mixture of two or kinds of them can be used.

Further, these organic polymers can be used in combination with other polymers. For example, as a mixture containing polythiophene, poly(3,4-ethylenedioxythiophene/polystyrene sulfonic acid) (PEDOT/PSS) or the like can be exemplified.

Among these, preferably, the hole transport layer 4′ is primarily formed of the organic polymer. This is because the organic polymer has excellent hole transport ability. Further, since the organic polymer has relatively excellent chemical resistance (solvent resistance), as described below, when the dye layer D′ is formed by the liquid film-deposition method, the selection range of the solvent (solution or dispersion medium) to be used for preparing the material for dye layer formation is widened. Further, by widening the selection range of the solvent, the selection range of the dye to be used for the dye layer D′ is also widened.

Further, the average molecular weight of the organic polymer is preferably 8000 or more, and more preferably, about 10000 to 15000. As such, by using the organic polymer having a relatively high molecular weight, the above-described effect can be further improved. Moreover, if the average molecular weight is increased and exceeds the upper limit value, according to the kind of the organic polymer, the kinds of the solvents obtained by dissolving the organic polymer may be drastically decreased.

As such an organic polymer, among the above-described organic polymers, it is preferable to use an organic polymer having an arylamine skeleton, such as polyarylamine, an organic polymer having a fluorene skeleton, such as fluorene-bithiophene copolymer, or an organic polymer having both the arylamine skeleton and the fluorene skeleton, such as fluorene-arylamine copolymer. These organic polymers have excellent hole transport ability and chemical resistance.

The average thickness of the hole transport layer 4′ is not particularly limited. For example, the average of the hole transport layer 4′ is preferably about 0.1 to 100 μm, and more preferably, about 1 to 30 μm.

The dye layer D′ is provided so as to come into contact with the hole transport layer 4′.

The dye layer D′ is a light-receiving layer (photosensitive layer) that receives light and generates the electrons and the holes.

And then, as shown in FIG. 4, macroscopically, the interface of the dye layer D′ and the hole transport layer 4′ is substantially in parallel with the anode 3′. Further, as shown in FIG. 5, microscopically, the dye layer D′ and the hole transport layer 4′ are made uneven (superimposed) in a concavo-convex shape at the interface.

Accordingly, the contact area of the dye layer D′ and the hole transport layer 4′ can be increased, and the holes generated in the dye layer D′ can be efficiently delivered to the hole transport layer 4′.

As the dye forming the dye layer D′, pigments and dyes can be used singly or in combination.

Here, as the pigments, various pigments, such as organic pigments and inorganic pigments, can be used. As the organic pigments, phthalocyanine-based pigments, such as phthalocyanine green, phthalocyanine blue, and the like, azo-based pigments, such as fast yellow, disazo yellow, condensed azo yellow, benzimidazolone yellow, dinitroaniline orange, benzimidazolone orange, toluidine red, permanent carmine, permanent red, naphthol red, condensed azo red, benzimidazolone carmine, benzimidazolone brown, and the like, anthraquinone-based pigments, such as anthrapyrimidine yellow, anthraquinonyl red, and the like, azomethine-based pigments, such as azomethine yellow (copper) and the like, quinophthalone-based pigments, such as quinophthalone yellow and the like, isoindoline-based pigments, such as isoindoline yellow and the like, nitroso-based pigments, such as dioxine yellow (nickel) and the like, perinone-based pigments, such as perinone orange and the like, quinacridone-based pigments, such as quinacridone magenta, quinacridone maroon, quinacridone scarlet, quinacridone red, and the like, perylene-based pigments, such as perylene red, perylene maroon, and the like, pyrropyrrol-based pigments, such as diketo pyrropyrrol red and the like, and dioxazine-pigments, such as dioxazine violet and the like, can be exemplified. As the inorganic pigments, carbon-based pigments, such as carbon black, lamp black, furnace black, ivory black, graphite, fullerene, and the like, chromate-based pigments, such as chrome yellow, molybdate orange, and the like, sulfide-based pigments, such as cadmium yellow, cadmium lithopone yellow, cadmium orange, cadmium lithopone orange, vermilion, cadmium red, cadmium lithopone red, and the like, oxide-based pigments, such as ochre, titanium yellow, titanium-barium-nickel yellow, red iron oxide, red lead, umber, brown iron oxide, zinc iron chromite brown, chromium oxide, cobalt green, cobalt chromite green, cobalt titanate green, cobalt blue, cerulean blue, cobalt-alminum-chromium blue, black iron oxide, manganese ferrite black, cobalt ferrite black, copper chromite black, copper chromite manganese black, and the like, hydroxide-based pigments, such as viridian and the like, ferrocyanide-based pigments, such as Prussian blue and the like, silicate-based pigments, such as ultramarine blue and the like, phosphate-based pigments, such as cobalt violet, mineral violet, and the like, and other pigments (such as cadmium sulfide, cadmium selenide, and the like), can be exemplified. In this case, one kind of these pigments or a mixture of two or more kinds of them can be used.

On the other hand, as the dyes, for example, metal complex dyes, such as RuL₂(SCN)₂, RuL₂Cl₂, RuL₂(CN)₂, Rutenium535-bisTBA (available from Solaronics, Inc.), and [RuL₂(NCS₂)₂]H₂O, and the like, cyan-based dyes, xanthene-based dyes, azo-based dye, hibiscus dyes, black berry dyes, raspberry dyes, pomegranate juice dyes, and chlorophyll dyes can be exemplified. In this case, one kind of these dyes or a mixture of two or more kinds of them can be used. Moreover, L in the above-described chemical formula indicates 2,2′-bipyridine or derivatives thereof.

The average thickness of the dye layer D′ is not particularly limited. For example, the average thickness of the dye layer D′ is preferably about 1 to 100 nm, and more preferably, about 20 to 50 nm.

The electron transport layer 5′ is provided so as to come into contact with the dye layer D′.

The electron transport layer 5′ has a function of capturing and transporting the electrons generated in the dye layer D′.

As the forming material of the electron transport layer 5′, one kind of various n-type inorganic semiconductor materials and various n-type organic semiconductor materials or a mixture of two or kinds of them can be used.

As the n-type inorganic semiconductor material, for example, metal oxides, such as titanium oxide (TiO₂), zirconium oxide (ZrO₂), zinc oxide (ZnO), aluminum oxide (Al₂O₃), tin oxide (SnO₂), ScVO₄, YVO₄, LaVO₄, NdVO₄, EuVO₄, GdVO₄, ScNbO₄, ScTaO₄, YNbO₄, YTaO₄, ScPO₄, ScAsO₄, ScSbO₄, ScBiO₄, YPO₄, YSbO₄, BVO₄, AlVO₄, GaVO₄, InVO₄, TlVO₄, InNbO₄, InTaO₄, and the like, metal sulfides, such as ZnS, CdS, and the like, metal selenides, such as CdSe and the like, metal or semiconductor carbides, such as TiC, SiC, and the like, or semiconductor nitrides, such as BN, B₄N, and the like, can be exemplified.

Further, as the n-type organic semiconductor material, for example, benzene-based compounds, such as 1,3,5-tris[(3-phenyl-6-tri-fluoromethyl)quinoxaline-2-yl]benzene (TPQ1), 1,3,5-tris[{3-(4-t-butylphenyl)-6-trisfluoromethyl}quinoxaline-2-yl]benzene (TPQ2), and the like, metal or non-metal phthalocyanine-based compounds, such as phthalocyanine, copper phthalocyanine (CuPc), iron phthalocyanine, and the like, low-molecular-weight materials, such as tris(8-hydroxyquinolinolate)aluminum (Alq₃) and the like, or high-molecular-weight materials, such as oxadiazole-based high-molecular-weight materials and triazole-based high-molecular-weight materials, can be exemplified.

Further, since titanium oxide has particularly high photosensitivity, when the electron transport layer 5′ is primarily formed of titanium oxide, the electron transport layer 5′ itself can generate the electrons. As a result, power generation efficiency (photoelectric conversion efficiency) of the solar cell 1′ can be further improved.

Further, the average thickness of the electron transport layer 5′ is not particularly limited. For example, the average thickness of the electron transport layer 5′ is preferably about 1 to 50 μm, and more preferably, about 5 to 30 μm.

On the electron transport layer 5′, the cathode 6′ is provided so as to face the anode 3′.

As the forming material of the cathode 6′, for example, metal oxides, such as indium zinc oxide (ITO), tin oxide having fluorine atoms (FTO), indium oxide (IO), or tin oxide (SnO₂), metal materials, such as aluminum, nickel, cobalt, platinum, silver, gold, copper, molybdenum, titanium, tantalum, and an alloy of them, carbon materials, such as graphite, and the like can be exemplified. One kind of the materials or a mixture of two or more kinds of them (for example, a laminate of multiple layers) can be used.

The average thickness of the cathode 6′ is suitably set according to the forming material, the use of the solar cell 1′, or the like, but is not particularly limited. For example, the average thickness can be set as follows.

If the cathode 6′ is formed of a metal oxide material (transparent conductive metal oxide material), the average thickness thereof is preferably about 0.05 to 5 μm, and more preferably, about 0.1 to 1.5 μm. Further, if the cathode 6′ is formed of a metal material or a carbon material, the average thickness thereof is preferably about 0.01 to 1 μm, and more preferably, about 0.03 to 0.1 μm.

Moreover, the cathode 6′ is not limited to a shape shown in the drawings. For example, the cathode 6′ can have a comb shape having plural teeth or the like. In this case, light transmits among the plural teeth and reaches the dye layer D′, and thus the cathode 6′ may be not substantially transparent. Accordingly, a selection range of the forming material or the forming method (manufacturing method) of the cathode 6′ can be widened.

Further, as the cathode 6′, a combination of the comb-shaped electrode and a layered electrode (for example, a laminate) can be used.

In such a solar cell 1′, if light is incident, the electrons are primarily excited in the dye layer D′, and thus the electrons (e⁻) and the holes (h⁺) are generated. Of them, the electrons move to the electron transport layer 5′ and the holes move to the hole transport layer 4′. As a result, a potential difference (photovoltaic force) is generated between the anode 3′ and the cathode 6′, and a current (photoexcited current) flows in the external circuit 10.

Such a solar cell 1′ can be manufactured as follows, for example.

In the present embodiment, the anode 3′, the hole transport layer 4′, the dye layer D′, the electron transport layer 5′, and the anode 6′ are sequentially laminated and formed.

Here, in contrast to the present embodiment, a case in which the solar cell is manufactured by sequentially laminating from the electron transport layer, that is, by forming the electron transport layer and then forming the dye layer, the hole transport layer, and the anode, as the forming material of the electron transport layer, a material, which can be resistant to the film deposition conditions of the dye layer, the hole transport layer, and the anode, is selected.

In such a solar cell, actually, as a usable forming material of the electron transport layer, a chemically stable inorganic semiconductor material is selected.

In contrast, in the present embodiment, if the cathode 6′ is formed after the electron transport layer 5′ is formed, the solar cell 1′ is finished.

Therefore, when selecting the forming material of the electron transport layer 5′, it is sufficient only to consider the film deposition condition of the cathode 6′. Further, when the cathode 6′ is provided by bonding of a sealant, it is not necessary to consider the film deposition condition of the cathode 6′.

For this reason, according to the present embodiment, the selection range of the forming material of the electron transport layer 5′ is widened. And then, by suitably selecting and using the dyes in combination, the solar cell 1′ having excellent power generation efficiency can be obtained.

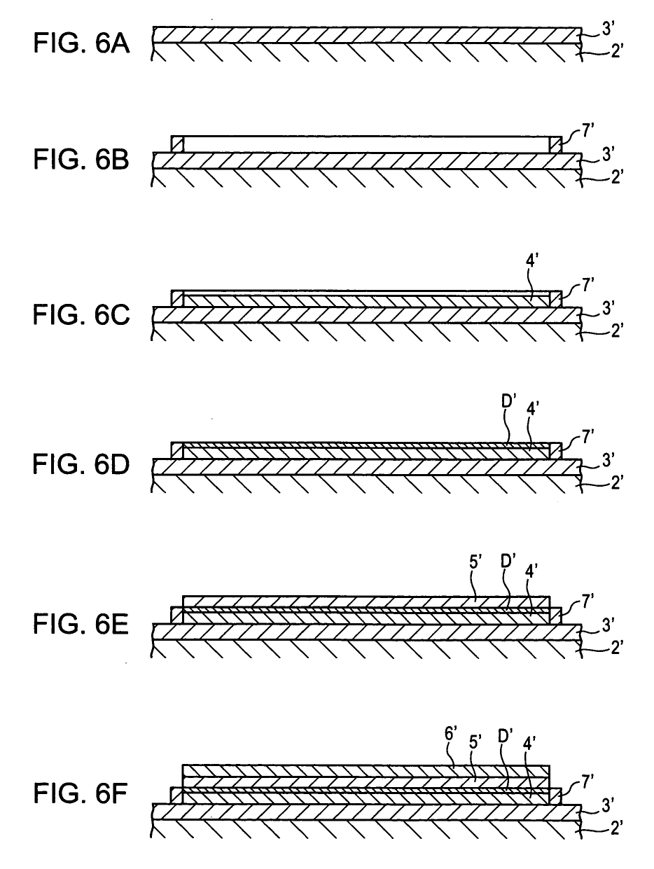

FIGS. 6A to 6F are diagrams (longitudinal cross-sectional views) illustrating a manufacturing process of the solar cell shown in FIG. 4. Moreover, hereinafter, for convenience of explanation, in FIG. 6, the upper side is referred to as ‘top’ and the lower side is referred to as ‘bottom’.

[1] First, the substrate 2′ is prepared, and, as shown in FIG. 6A, the anode 3′ is formed on the substrate 2′.

The anode 3′ can be formed, for example, by using a chemical vapor deposition method (CVD), such as plasma CVD, thermal CVD, or the like, a dry plating method, such as vacuum deposition, sputtering, ion plating, or the like, a vapor film-deposition method, such as a spraying method, a wet plating method, such as electrolytic plating, immersion plating, electroless plating, or the like, a liquid film-deposition method, such as a sol-gel method, a MOD method, or the like, bonding of a sealant, or the like.

[2] Next, as shown in FIG. 6B, a bank 7′ is formed on the anode 3′ so as to surround a region in which the hole transport layer 4′ is formed.

In the present embodiment, the hole transport layer 4′ and the dye layer D′ are formed by the liquid film-deposition method, and thus a height of the bank 7′ is set substantially equal to or slightly larger than the total thickness of the hole transport layer 4′ and the dye layer D′.

By providing the bank 7′, the shape of a layer to be formed can be accurately defined, and the hole transport layer 4′ and the dye layer D′ can be formed with high dimensional accuracy.

The bank 7′ can be obtained, for example, by supplying (coating) a resist material on the anode 3′ and then by exposing, developing, and patterning the resist material.

As the resist material to be used, a negative type for curing portions where light is irradiated or a positive type for dissolving portions where light is irradiated can be used.

As the negative-type resist material, for example, polycinnamic acid vinyl, polyvinyl azido benzal, acrylamide, polyimide, resin primarily containing novolac resin (for example, chemical amplification-type resin, such as novolac resin containing acid generator or cross-linking agent) or the like can be exemplified. On the other hand, as the positive-type resin material, for example, o-quinone diazid novolac resin, polyimide resin, or the like can be exemplified.

Further, as irradiation light, for example, ultraviolet rays (g rays, i rays, or the like), electron rays, or the like can be exemplified.

A method of supplying the resist material is not particularly limited. For example, various coating methods, such as a spin coating method, a casting method, a micro gravure coating method, a gravure coating method, a bar coating method, a roll coating method, a wire bar coating method, a dip coating method, a spray coating method, a screen printing method, a flexography method, an offset method, an ink jetting method, and the like can be used.

Moreover, by selectively supplying the negative-type resist material on the anode 3′ so as to have a shape corresponding to the bank 7′ to be formed, the development process can be omitted.

[3] Next, as shown in FIG. 6C, the hole transport layer 4′ is formed in a region inside the bank 7′ on the anode 3′ by the liquid film-deposition method (First Step).

According to the liquid film-deposition method, the hole transport layer 4′ can be easily formed at low cost, without using large-scale equipments.

First, a liquid material (solution or dispersion medium) containing the above-described p-type semiconductor material is prepared.

As the solvent or the dispersion medium to be used to prepare the liquid material, inorganic solvents, such as nitric acid, sulfuric acid, ammonia, hydrogen peroxide, water, carbon disulfide, carbon tetrachloride, and ethylene carbonate, and various organic solvents, such as ketone-based solvents, for example, methyl ethyl ketone (MEK), acetone, diethyl ketone, methyl isobutyl ketone (MIBK), methyl isopropyl ketone (MIPK), and cyclohexanone, alcohol-based solvents, for example, methanol, ethanol, isopropanol, ethylene glycol, diethylene glycol (DEG), and glycerol, ether-based solvents, for example, diethyl ether, diisopropyl ether, 1,2-dimethoxy ethane (DME), 1,4-dioxane, tetrahydrofuran (THF), tetrahydropyran (THP), anisole, diethylene glycol dimethyl ether (diglyme), and diethylene glycol ethyl ether (carbitol), cellosolve-based solvents, for example, methyl cellosolve, ethyl cellosolve, and phenyl cellosolve, aliphatic hydrocarbon-based solvents, for example, hexane, pentane, heptane, and cyclohexane, aromatic hydrocarbon-based solvents, for example, toluene, xylene, and benzene, aromatic heterocyclic compound-based solvents, for example, pyridine, pyrazine, furan, pyrrole, thiophene, and methyl pyrrolidone, amide-based solvents, for example, N,N-dimethylformamide (DMF), and N,N-dimethylacetamide (DMA), halogen compound-based solvents, for example, chlorobenzene, dichloromethane, chloroform, and 1,2-dichloroethane, ester-based solvents, for example, ethyl acetate, methyl acetate and ethyl formate, sulfur compound-based solvents, for example, dimethyl sulfoxide (DMSO) and sulfolane, nitrile-based solvents, for example, acetonitrile, propionitrile, and acrylonitrile, organic acid-based solvents, for example, formic acid, acetic acid, trichloroacetic acid, and trifluoroacetic acid, and mixed solvents containing them can be exemplified.

When the organic polymer is used as the p-type semiconductor material, among these, nonpolar solvents are suitably used. For example, aromatic hydrocarbon-based solvents, such as xylene, toluene, cyclohexylbenzene, dihydrobenzofuran, trimethylbenzene, and tetramethylbenzene, aromatic heterocyclic compound-based solvents, such as pyridine, pyrazine, furan, pyrrole, thiophene, and methyl pyrrolidone, and aliphatic hydrocarbon-based solvents, such as hexane, pentane, heptane, and cyclohexane, can be exemplified. These solvents can be used singly or in combination.

Next, the liquid material is supplied on the anode 3′ so as to form a liquid film.

As a method of supplying the liquid material (liquid film-deposition method), among the above-described coating methods, in particular, it is preferable to use an inkjet printing method (liquid droplet discharge method). By using the inkjet printing method, the liquid film can be formed with high dimensional accuracy, without wasting the liquid material.

Next, the solvent or the dispersion medium is removed from the liquid film. Accordingly, the hole transport layer 4′ is obtained.

As a method of removing the solvent or the dispersion medium, for example, leaving under an air pressure or under a reduced pressure, heating, or blowing of inert gas can be exemplified.

Moreover, the hole transport layer 4′ may be formed by using the first liquid material and the second liquid material described in the first embodiment.

[4] Next, as shown in FIG. 6D, the dye layer D′ is formed on the hole transport layer 4′ by the liquid film-deposition method (Second Step).

According to the liquid film-deposition method, the dye layer D′ can be easily formed at low cost, without using large-scale equipments.

The dye layer D′ can also be formed in the same manner as that of the hole transport layer 4′.

That is, as the liquid film-deposition method of the dye layer D′, it is also preferable to use the inkjet printing method (liquid droplet discharge method). By using the inkjet printing method, the liquid film can be formed with high dimensional accuracy, without wasting the liquid material.

Further, in this case, in order to prepare the liquid material for dye layer formation, among the above-described solvents or dispersion mediums (solvent), it is preferable to use a material obtained by swelling the hole transport layer 4′. Accordingly, as described above, microscopically, the interface of the dye layer D′ and the hole transport layer 4′ can be made uneven in the concavo-convex shape (see FIG. 5), and thus the contact area between them can be increased. For this reason, the holes can be smoothly delivered from the dye layer D′ to the hole transport layer 4′. As a result, power generation efficiency of the solar cell 1′ can be further improved.

Moreover, the bank 7′ may be removed once after the step [3], and then a new one may be formed again.

[5] Next, as shown in FIG. 6E, the electron transport layer 5′ is formed on the dye layer D′ (Third Step).

The electron transport layer 5′ can be formed in the same manner as that of the anode 3′.

[6] Next, as shown in FIG. 6F, the cathode 6′ is formed on the electron transport layer 5′.

The cathode 6′ can also be formed in the same manner as that of the anode 3′.

Moreover, when the electron transport layer 5′ and/or the anode 6′ are formed by using the liquid film-deposition method, the height of the bank 7′ to be formed may be set accordingly.

Further, in the finished product of the solar cell 1′, the bank 7′ may remain without being removed, or may be removed.

[7] Next, the end portions of the external circuit 10 are correspondingly connected to the anode 3′ and the cathode 6′.

Through the above-described steps, the solar cell 1′ of the second embodiment (the photoelectric conversion element of the invention) is manufactured.

Moreover, in the present embodiment, a case in which the hole transport layer 4′ and the dye layer D′ are formed by the liquid film-deposition method has been described. However, in the invention, one or both of them may be formed by a method other than the liquid film-deposition method, for example, a vapor film-deposition method.

Electronic apparatuses of the invention include the solar cell 1 (or 1′).

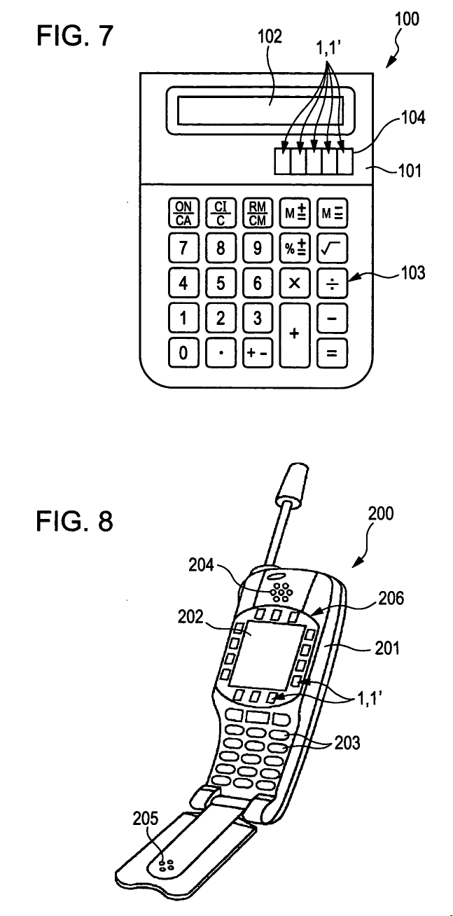

Hereinafter, the electronic apparatuses of the invention will be described with reference to FIGS. 7 and 8.

FIG. 7 is a plan view showing an electronic calculator, to which the photoelectric conversion element of the invention is applied. FIG. 8 is a perspective view showing a cellular phone (including PHS), to which the photoelectric conversion element of the invention is applied.

The electronic calculator 100 shown in FIG. 7 has a main body portion 101, a display unit 102 provided on a top surface (front surface) of the main body portion 101, a plurality of operating buttons 103, and a solar cell installment portion 104.

In the configuration shown in FIG. 7, in the solar cell installment portion 104, five solar cells 1 (or 1′) are arranged to be connected in series.

The cellular phone 200 shown in FIG. 8 has a main body portion 201, a display unit 202 provided on a front surface of the main body portion 201, a plurality of operating buttons 203, a receiver 204, a transmitter 205, and a solar cell installment portion 206.

In the configuration shown in FIG. 8, the solar cell installment portion 206 is provided so as to surround the periphery of the display unit 202, and a plurality of solar cells 1 (or 1′) are arranged to be connected in series.

As described above, the method of manufacturing the photoelectric conversion element, the photoelectric conversion element, and the electronic apparatus of the invention has been described by way of the embodiments with reference to the drawings, but the invention is not limited thereto.

For example, the individual parts of the photoelectric conversion element and the electronic apparatus can be substituted with arbitrary configurations, which can exhibit the same functions.

Further, for example, in the method of manufacturing the photoelectric conversion element of the invention, two or more arbitrary configurations of the first and second embodiments may be combined.

Moreover, the photoelectric conversion element of the invention can be applied various elements (light-receiving elements), such as optical sensors or optical switches, which receive light and convert light into electrical energy, in addition to the solar cell.

Further, in the photoelectric conversion element of the invention, unlike those shown in the drawings, an incident direction of light may be reversed. That is, the incident direction of light is arbitrary.

### EXAMPLES

Next, specified examples of the invention will be described.

1. Manufacture of Solar Cell (Photoelectric Conversion Element)

### Example 1

By doing as follows, the solar cell shown in FIG. 1 was manufactured.

First, a soda glass substrate of a size of 30 mm vertical×35 mm horizontal×1.0 mm thickness was prepared.

And then, the soda glass substrate was immersed in a cleaning solution of 85° C. (a mixed solution of sulfuric acid and aqueous hydrogen peroxide) for cleaning so as to clean its surface.

Next, an FTO electrode (cathode or first electrode) of a size of 30 mm vertical×35 mm horizontal×1 μm thickness was formed on the soda glass substrate by a vapor deposition method.

Next, the barrier layer was formed in a region of a size of 30 mm vertical×30 mm horizontal on the FTO electrode. This was performed as follows.

First, titanium tetraisopropoxide was dissolved in 2-n-butoxyethanol such that the concentration thereof became 0.5 mol/L. Subsequently, diethanolamine was added to this solution. Accordingly, the material for barrier layer formation was obtained.

Moreover, the compound ratio of diethanolamine and titanium tetraisopropoxide was 2:1 (mole ratio). Further, viscosity of the resultant material for barrier layer formation was 3 cP (normal temperature).

The material for barrier layer formation was coated by spin coating, and a film was obtained. Moreover, spin coating was performed with the rotation number of 1500 rpm.

Subsequently, the film was loaded on a hot plate and was subjected to a heat treatment at 160° C. for 10 minutes so as to dry the film. In addition, a heat treatment was performed within an oven at 480° C. for 30 minutes so as to remove remaining organic components in the film.

With drying and removal of the organic components as one cycle, ten cycles were performed repeatedly.

Accordingly, the barrier layer of the void ratio of less than 1% was obtained. Moreover, the average of the barrier layer was 0.9 μm.

Next, the electron transport layer was formed on the barrier layer so as to have the substantially same shape as that of the barrier layer in plan view. This was performed as follows.

First, powder of rutile-type titanium dioxide and power of anatase-type titanium dioxide were mixed so as to prepare power of titanium dioxide.

Moreover, the average particle size of the powder of titanium dioxide was 40 nm, and the compound ratio of the powder of rutile-type titanium dioxide and the powder of anatase-type titanium dioxide was 60:40 (weight ratio).

Further, titanium tetraisopropoxide was dissolved in 2-propanol such that the concentration thereof became 1 mol/L. Subsequently, acetic acid and distilled water were mixed into this solution.

Moreover, the compound ratio of acetic acid and titanium tetraisopropoxide was 1:1 (mole ratio), and the compound ratio of distilled water and titanium tetraisopropoxide was 1:1 (mole ratio).

Subsequently, the powder of titanium dioxide previously prepared was mixed by a predetermined amount into this solution. In addition, the suspension was diluted with 2-propanol such that the dilution factor became 2. Accordingly, the material for electron transport layer formation was prepared.

And then, the soda glass substrate, on which the FTO electrode and the barrier layer were formed, was loaded on the hot plate which was heated at 140° C., and the material for electron transport layer formation was dripped and dried. With this operation as one cycle, seven cycles were performed repeatedly.

Accordingly, the electron transport layer having the void ratio of 34% was obtained. Moreover, the average of the electron transport layer was 7.2 μm.

Moreover, the total resistance value of the barrier layer and the electron transport layer in the thicknesswise direction was 1 kΩ/cm² or more.

Next, the laminate of the soda glass substrate, the FTO electrode, the barrier layer, and the electron transport layer was immersed in a saturated ethanol solution of ruthenium trisbipyridyl (dye) and drawn out therefrom, and then ethanol was volatilized by air drying. In addition, the laminate was dried in a clean oven at 80° C. for 0.5 hour and left for a night. Accordingly, the dye layer was formed along the outer surface of the electron transport layer and the inner surfaces of the voids.

Next, the hole transport layer was formed so as to come into contact with the dye layer and to have the substantially same shape as that of the electron transport layer in plan view. This was performed as follows.

First, polyphenylamine (average molecular weight: 2000) as the first semiconductor material was dissolved in toluene such that the concentration thereof became 1 percent by weight, and then the first liquid material was prepared. Further, polyphenylamine (average molecular weight: 20000) as the second semiconductor material was dissolved in xylene such that the concentration thereof became 1 percent by weight, and then the second liquid material was prepared.

Moreover, viscosity of the first liquid material was 2 cP (normal temperature), and viscosity of the second liquid material was 7 cP (normal temperature). Further, the increase rate of viscosity of the first liquid material according to the increase in concentration of polyphenylamine was lower than the increase rate of viscosity of the second liquid material according to the increase in concentration of polyphenylamine.

And then, first, the first liquid material was supplied from the side of the electron transport layer opposite to the FTO electrode by the spin coating method (1000 rpm×30 seconds) so as to cover the voids of the electron transport layer, while supersonic vibration was applied to the electron transport layer, and was dried. Subsequently, the second liquid material was supplied by the ink jetting method and was dried.

Moreover, the average thickness of the resultant hole transport layer (excluding the part entered into the void of the electron transport layer) was 20 μm.

Next, a platinum electrode (anode or second electrode) having a size of 30 mm vertical×30 mm horizontal×0.1 mm thickness was formed on the hole transport layer by the vapor deposition method.

Next, the end portions of the external circuit were correspondingly connected to the FTO electrode and the platinum electrode, such that the solar cell 1 was finished.

### Example 2

Excluding that the second liquid material was not used, the solar cell was manufactured in the same manner as that of Example 1.

### Example 3

Excluding that the first liquid material was not used, the solar cell was manufactured in the same manner as that of Example 1.

2. Evaluation

Pseudo sunlight was irradiated onto the solar cells obtained in the individual examples on AM 1.5 conditions, and photoelectric conversion efficiency was measured.

As a result, when photoelectric conversion efficiency in the solar cell of Example 2 was ‘1’, power generation efficiency in the solar cell of Example 1 was about twice, and power generation efficiency in the solar cell of Example 3 was about 0.7 times.

Moreover, when the solar cell is manufactured in the same manner as that of each of the examples by using fluorene-arylamine copolymer, fluorene-bithiophene copolymer, and derivatives of them, instead of polyphenylamine (polyarylamine), as the first semiconductor material and the second semiconductor material, and the evaluation is performed in the same manner, the same effect is obtained.

What is claimed is:

1. A method of manufacturing a photoelectric conversion element, in which a first carrier transport layer, a dye layer, and a second carrier transport layer are interposed between an anode and a cathode, comprising:
forming the first carrier transport layer;
forming the dye layer so as to come into contact with the first carrier transport layer;
forming the second carrier transport layer so as to come into contact with the dye layer; and
forming at least one of the first carrier transport layer and the second carrier transport layer by a liquid film-deposition method.

2. The method of manufacturing a photoelectric conversion element according to claim 1,
wherein the first carrier transport layer is a porous electron transport layer, and the second carrier transport layer is a hole transport layer, and
in the forming of the second carrier transport layer, the hole transport layer is formed by the liquid film-deposition method.

3. The method of manufacturing a photoelectric conversion element according to claim 2,
wherein, in the forming of the second carrier transport layer, when the hole transport layer is formed by supplying a first liquid material containing a first semiconductor material and then supplying a second liquid material containing a second semiconductor material from a side of the electron transport layer opposite to the cathode, the first liquid material has viscosity lower than that of the second liquid material at normal temperature.

4. The method of manufacturing a photoelectric conversion element according to claim 3,
wherein, in the forming of the second carrier transport layer, the first semiconductor material is filled so as to cover voids of the electron transport layer.

5. The method of manufacturing a photoelectric conversion element according to claim 3,
wherein, in the forming of the second carrier transport layer, the first liquid material is supplied while vibration is applied to the electron transport layer and/or the first liquid material.

6. The method of manufacturing a photoelectric conversion element according to claim 3,
wherein an increase rate of viscosity of the first liquid material according to an increase in concentration of the first semiconductor material is lower than an increase rate of viscosity of the second liquid material according to an increase in concentration of the second semiconductor material.

7. The method of manufacturing a photoelectric conversion element according to claim 3,
wherein the first semiconductor material and the second semiconductor material are organic high-molecular-weight materials.

8. The method of manufacturing a photoelectric conversion element according to claim 7,
wherein the first semiconductor material and the second semiconductor material are organic polymers of the same kind, and an average molecular weight of the first semiconductor material is smaller than an average molecular weight of the second semiconductor material.

9. The method of manufacturing a photoelectric conversion element according to claim 8,
wherein the average molecular weight of the first semiconductor material is 10000 or less.

10. The method of manufacturing a photoelectric conversion element according to claim 8,
wherein the average molecular weight of the second semiconductor material is 15000 or more.

11. The method of manufacturing a photoelectric conversion element according to claim 8,
wherein the organic polymer is polyarylamine, fluorene-arylamine copolymer, fluorene-bithiophene copolymer, or its derivative.

12. The method of manufacturing a photoelectric conversion element according to claim 3,
wherein the first semiconductor material and the second semiconductor material are the same kind.

13. The method of manufacturing a photoelectric conversion element according to claim 1,
wherein the first carrier transport layer is a hole transport layer, and the second carrier transport layer is an electron transport layer, and
in the forming of the first carrier transport layer, the hole transport layer is formed by a liquid film-deposition method.

14. The method of manufacturing a photoelectric conversion element according to claim 13,
wherein the hole transport layer is primarily formed of an organic polymer.

15. The method of manufacturing a photoelectric conversion element according to claim 13,
wherein, in the forming of the dye layer, the dye layer is formed by the liquid film-deposition method, and a liquid, which is obtained by swelling the hole transport layer, is used to prepare a liquid material for dye layer formation.

16. The method of manufacturing a photoelectric conversion element according to claim 2,
wherein, as the liquid film-deposition method for forming the hole transport layer, a liquid droplet discharge method is used.

17. The method of manufacturing a photoelectric conversion element according to claim 1,
wherein, in the forming of the dye layer, the dye layer is formed by the liquid film-deposition method.

18. The method of manufacturing a photoelectric conversion element according to claim 17,
wherein, as the liquid film-deposition method for forming the dye layer, a liquid droplet discharge method is used.

19. The method of manufacturing a photoelectric conversion element according to claim 1, further comprising:
forming, prior to forming the individual layers, a bank that defines a shape of a corresponding layer.
